(19) United States
(12) Patent Application Publication
(10) Pub. No.: US 2015/0227054 A1
(43) Pub. Date: Aug. 13, 2015

(54) EXTREME ULTRAVIOLET RADIATION EXPOSURE APPARATUS AND METHOD OF LITHOGRAPHY THEREBY

(71) Applicant: Kabushiki Kaisha Toshiba, Minato-ku (JP)

(72) Inventors: Yukinobu MIYAMOTO, Yokkaichi-shi (JP); Kazuo TAWARAYAMA, Yokkaichi-shi (JP)

(73) Assignee: Kabushiki Kaisha Toshiba, Minato-ku (JP)

(21) Appl. No.: 14/279,467

(22) Filed: May 16, 2014

Related U.S. Application Data
(60) Provisional application No. 61/937,098, filed on Feb. 7, 2014.

(51) Int. Cl. G03F 7/20

(52) U.S. Cl. CPC G03F 7/70033

(57) ABSTRACT

According to one embodiment, an EUV radiation exposure apparatus includes a vacuum chamber, an EUV radiation exposing light source installed in the vacuum chamber, and an ionizer that generates positive or negative ions. The ionizer is installed in the vacuum chamber and is driven with driving of the EUV radiation exposing light source.

### CROSS-REFERENCE TO RELATED APPLICATIONS

This application is based upon and claims the benefit of priority from Provisional U.S. Patent Application No. 61/937,098, filed on Feb. 7, 2014; the entire contents of all of which are incorporated herein by reference.

### FIELD

Embodiments described herein relate generally to an extreme ultraviolet radiation exposure apparatus and a method of lithography thereby.

### BACKGROUND

Research and development on an extreme ultraviolet (EUV) radiation exposure apparatus and method of lithography thereby using ultra-short wavelength of 13.5 nanometers as a next-generation exposure technology has been promoted for manufacturing post-22-nanometer-generation advanced semiconductor device. Because this EUV radiation exposure technology enables a semiconductor device with extremely narrow line-width, the technology is regarded as “ultimate exposure technology”.

Conventionally, because a vacuum chamber of an EUV radiation exposure apparatus is kept vacuous, the EUV radiation exposure apparatus for performing EUV lithography has a problem of contamination by carbon against optical elements such as an EUV-light reflecting mirror which is used in reduced projection lithography. When a wafer covered with photoresist is introduced into the vacuum chamber of the apparatus and EUV light radiates the wafer to form a pattern of the photoresist, solvent remained in the apparatus evaporates or resin constituting the photoresist is decomposed or desorbed, so that degas including organic compounds is emitted in the vacuum chamber. The degas including organic compounds is easy to be charged and adheres to surfaces as foreign substances because the vacuum chamber of the EUV radiation exposure apparatus is vacuous. Accordingly, a technique that uses hydrogen (hydrogen radicals) to clean the foreign substances in the vacuum chamber of the EUV radiation exposure apparatus is disclosed.

### BRIEF DESCRIPTION OF THE DRAWINGS

FIGS. 1A and 1B are cross-sectional views schematically illustrating a configuration of an EUV radiation exposure apparatus according to an embodiment of the present invention and a configuration of a method of lithography using the EUV radiation exposure apparatus;

FIG. 2 illustrates an EUV radiation exposure head in the process of EUV radiation exposure in detail;

FIG. 3 illustrates the EUV radiation exposure head in the process of EUV radiation exposure in detail, and illustrates a state where a mask 23 and a wafer stage S are moved in a mask moving direction D_{M} and a wafer-stage moving direction D_{W}, respectively, from a state shown in FIG. 2;

FIG. 4 is a top view of a wafer 10 in an exposure process;

FIG. 5 illustrates a relation between a degree of vacuum and a charge elimination time;

FIG. 6 illustrates a relation between a charge elimination time and a distance between a light-source output window and a charged plate;

FIGS. 7A and 7B are timing charts respectively showing a driving state of an EUV radiation exposing light source of the EUV radiation exposure head and an ionizer in the lithography method according to the first embodiment;

FIGS. 8A and 8B are timing charts respectively showing a driving state of an EUV radiation exposing light source of an EUV radiation exposure head and an ionizer in a lithography method according to a second embodiment; and

FIGS. 9A and 9B are cross-sectional views schematically illustrating a configuration of an EUV radiation exposure apparatus according to a comparative example and a configuration of a method of lithography using the EUV radiation exposure apparatus.

### DETAILED DESCRIPTION

In general, according to one embodiment, an EUV radiation exposure apparatus includes a vacuum chamber, an EUV radiation exposing light source installed in the vacuum chamber, and an ionizer that generates positive or negative ions.

Exemplary embodiments of an EUV radiation exposure apparatus will be explained below in detail with reference to the accompanying drawings. The present invention is not limited to the following embodiments.

### First Embodiment

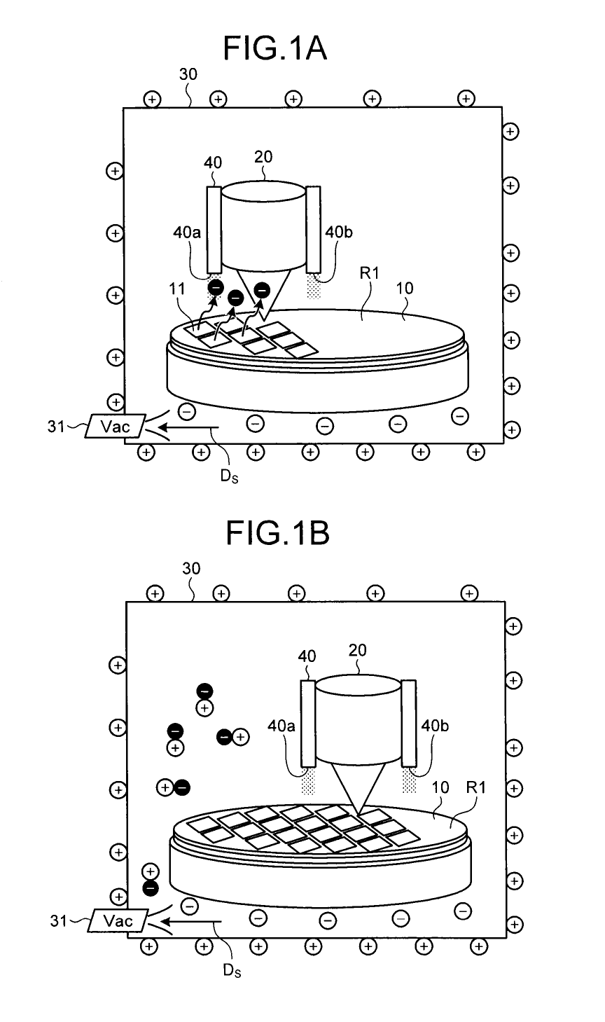

FIGS. 1A and 1B are cross-sectional views schematically illustrating a configuration of an EUV radiation exposure apparatus according to an embodiment of the present invention and a configuration of a method of lithography using the EUV radiation exposure apparatus.

When EUV light from an EUV radiation exposure head 20 is radiated to a photoresist R1 on a surface of a wafer 10, the EUV radiation exposure apparatus according to the embodiment of the present invention radiates ionizer light by an ionizer 40 to degas including organic compounds, which is generated after the EUV light radiation, to neutralize charged degas. As shown in FIGS. 1A and 1B, due to the ionizer light radiation by the ionizer 40, degas is neutralized to remove charges from degas in a chamber 30 immediately after degas is generated. In this case, soft X-rays are used as ionizer light. In this way, when EUV light is radiated to the photoresist, charge is removed by the ionizer from degas including organic compounds and generated after the light radiation.

That is, the EUV radiation exposure apparatus according to the embodiment of the present invention includes the EUV radiation exposure head 20 for exposing photoresist R1 that is arranged to face the wafer 10 to which the photoresist R1 is coated, the ionizer 40 that is attached to the EUV radiation exposure head 20 and has two ion generation ports 40a and 40b on both side surfaces thereof, respectively, and the chamber 30 that houses these elements therein. The inside of the chamber 30 is kept at a desired degree of vacuum by a vacuum suction device 31. The ionizer 40 is installed in the vacuum chamber and is driven in conjunction with driving of the EUV radiation exposure head 20 and generates positive or negative ions. Polarity of the ions applied by the ionizer 40 is determined according to a type of the photoresist R1.

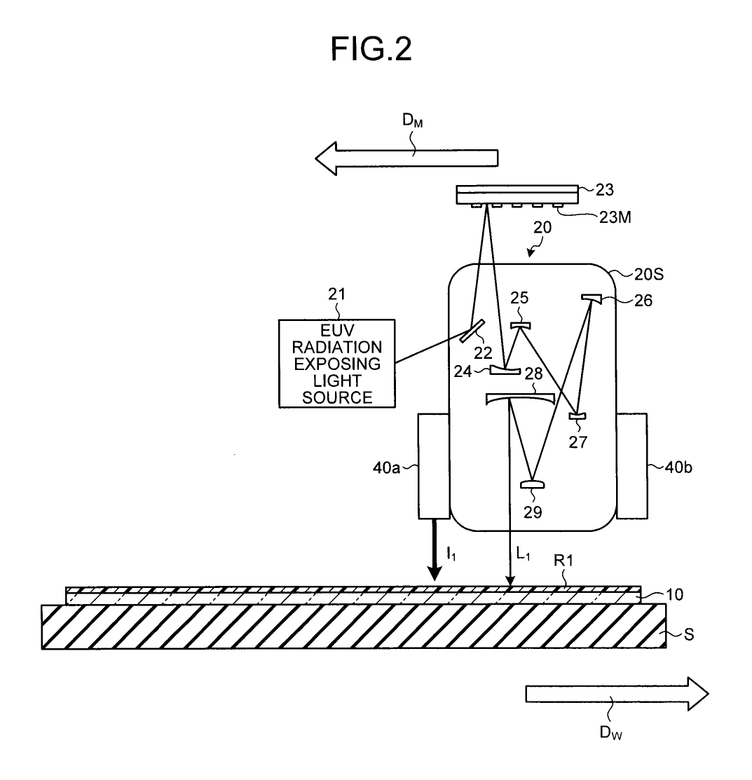

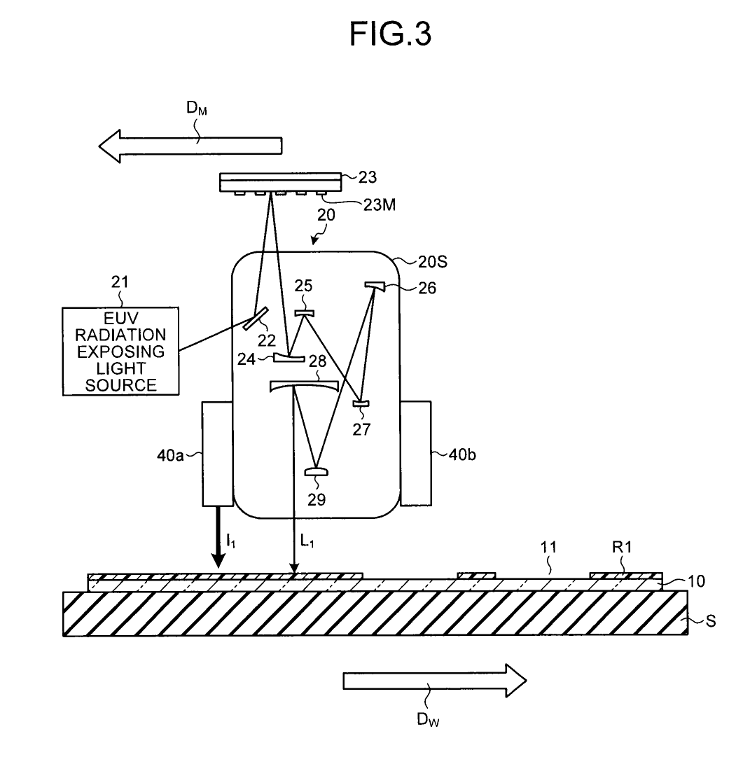

FIGS. 2 and 3 illustrate the EUV radiation exposure head 20 in the process of EUV radiation exposure in detail and FIG. 3 illustrates a state where a mask 23 and a wafer stage S are moved along the mask moving direction D_{M} and the wafer-stage moving direction D_{W}, respectively, from a state shown in FIG. 2. The EUV radiation exposure head 20 includes a projection optical system in a housing 20S to reflect EUV light from an EUV radiation exposing light source 21 installed outside of the housing 20S and to guide reflected light from a mask pattern 23M on the mask 23 installed outside of the housing 20S to the photoresist R1 on the wafer 10. The projection optical system includes a reflecting mirror 22, a condensing reflecting lens 24, and optical lens 25, 26, 27, 28, and 29 and focuses the reflected light from the mask pattern 23M on the mask 23 onto the photoresist R1 as exposure light L₁.

By moving the mask 23 and the wafer stage S in the mask moving direction D_{M} and the wafer-stage moving direction D_{W}, respectively, exposure is sequentially performed, the photoresist R1 in an exposure area 11 reacts due to exposure energy of the exposure light L₁, and a latent image pattern is formed, as shown by a top view of the wafer 10 in an exposure process in FIG. 4. In this case, a photosensitizing agent (PAG) in the photoresist R1 reacts to the light, so that the latent image pattern is formed. The comparison between FIGS. 2 and 3 indicates that the pattern is sequentially formed.

The ionizer 40 has the ion generation ports 40a and 40b, which are arranged on opposite side surfaces on upstream and downstream sides of the EUV radiation exposure head 20, respectively, in the mask moving direction D_{M} and the wafer-stage moving direction D_{W} as shown in FIG. 4. The ion generation ports 40a and 40b are installed to be on an area where the exposure light L₁ is focused on the wafer 10 and on a path of light from the EUV radiation exposing light source 21. As mentioned above, the photoresist R1 is applied on the surface of the wafer 10 and the direction of the wafer 10 is identified based on the position of a notch 10n to perform alignment. With this configuration, immediately after degas is generated by exposure, ionizer radiation light is applied from the ion generation ports 40a and 40b and elimination of charges is performed efficiently. Furthermore, because the ion generation ports 40a and 40b are arranged on the opposite side surfaces on the upstream and downstream sides of the EUV radiation exposure head 20, respectively, one of the ion generation ports 40a and 40b can be selected according to the direction of the relative movement between the processing target object and the EUV radiation exposure head 20 for exposure.

The ionizer 40 having a radiation wavelength range from 115 nanometers to 400 nanometers, and an operation temperature range from 10° C. to 40° C. (a storage temperature range from 0° C. to 60° C.) and a humidity equal to or lower than 80% (a storage humidity range equal to or lower than 85%) in the case of an air cooling method by a cooling fan was used. A window material thereof was MgF₂. An input voltage thereof was AC 100 volts to 240 volts.

The EUV radiation exposing light source 21 is attached to the EUV radiation exposure head 20 that is formed to be capable of relatively moving with respect to the wafer 10, and the ionizer 40 is also fixed to the EUV radiation exposure head 20. This configuration realizes elimination of charges at an appropriate position with respect to an exposure position without the need of alignment.

In this case, the EUV radiation exposing light source having a luminescence peak near a wavelength of 13.5 nanometers, power from 10 watts to 120 watts, and a frequency about from 2 kHz to 10 kHz is used.

The ionizer 40 is activated or deactivated according to the activation and deactivation of the EUV radiation exposing light source 21. The ionizer 40 can be activated or deactivated with a delay time according to the activation and deactivation of the EUV radiation exposing light source 21. With this configuration, elimination of charges from degas can be realized immediately after generation of the degas due to exposure and a state where the degas is difficult to reattach to the apparatus can be obtained.

In the embodiment mentioned above, as ionizer light, that is, electron beams obtained from the ionizer 40, electron beams of a wavelength of 160 nanometers are used. However, electron beams of a wavelength from 115 nanometers to 400 nanometers can be used. Preferably, electron beams of a wavelength from 150 nanometers to 180 nanometers can be used. When the electron beams of a wavelength from 115 nanometers to 400 nanometers are used, the photoresist for EUV radiation exposure does not react thereto and thus there is no influence on pattern formation even when ionizer light is radiated to the photoresist. Particularly when electron beams of a wavelength from 150 nanometers to 180 nanometers are used, charges can be eliminated efficiently.

For example, a polymer bound PAG resist or a resist using a polyhydroxystyrene (PHS) or acrylic base resin is used as the photoresist R1. In this case, the film thickness of the photoresist R1 is set from 30 nanometers to 60 nanometers.

A method of lithography using the EUV radiation exposure apparatus is explained next.

As shown in FIG. 2, the wafer 10 having the photoresist R1 applied thereto is first mounted on the wafer stage S in the chamber 30, and the EUV radiation exposure head 20 and the mask 23 are aligned to enable desired pattern drawing on the wafer 10. The inside of the chamber 30 is kept at a desired degree of vacuum by the vacuum suction device 31. In this case, the inside of the chamber 30 is evacuated to be at about 1×10⁻⁴ Pascal to 2×10⁻⁷ Pascal (the direction of evacuation is denoted by Dₛ in FIGS. 1A,1B). Meanwhile, the ionizer 40 is preheated for about 25 seconds.

In this case, the wafer 10 to which a polymer bound PAG resist is applied in a film thickness of about 50 nanometers using a spinner and which is prebaked at a temperature from 80° C. to 120° C. for about 1 minute is used.

As shown in FIGS. 2 to 4, the EUV radiation exposure head 20 is driven by a control system (not shown) and the EUV radiation exposing light source 21 installed outside of the housing 20S is turned on, so that the EUV light is reflected by the reflecting mirror 22 and is applied to the mask pattern 23M on the mask 23 placed outside of the housing 20S. Reflected light from the mask pattern 23M on the mask 23 is focused on the photoresist R1 by the projection optical system including the reflecting mirror 22, the condensing reflecting lens 24, and the optical lens 25, 26, 27, 28, and 29 as the exposure light L₁. The mask 23 and the wafer stage S are moved in the mask moving direction D_{M} and the wafer-stage moving direction D_{W}, respectively, for each shot, thereby sequentially performing exposure. Immediately after exposure, negative ions I₁ are generated from the ion generation port 40a of the ionizer 40, and resist components that are decomposed by exposure on the wafer 10 and positively charged are neutralized by the negative ions I₁ to eliminate charges. A decomposition product is subject to charge elimination immediately after generation, and FIG. 3 illustrates a state where some shots of exposure are completed and the wafer 10 is moved. In the present embodiment, the EUV radiation exposure head 20 is not moved and the mask 23 and the wafer stage S are moved. That is, when EUV light radiation is performed from the EUV radiation exposure head 20 to the photoresist R1 on the surface of the wafer 10, soft X-ray radiation by the ionizer 40 is performed to degas including organic compounds generated after the EUV light radiation to neutralize generated negative ions. In this way, as shown in FIG. 1B, charged degas is neutralized in the chamber 30 by soft X-ray radiation performed by the ionizer 40 to eliminate charges immediately after generation of the degas. The charged degas is subject to charge elimination immediately after generation, whereby attachment thereof to various interfaces in the apparatus can be suppressed and a state where the degas is difficult to reattach thereto can be obtained. Accordingly, it is unnecessary to perform cleaning of attached substances separately. Even when the cleaning is to be performed, the use amount of hydrogen to be used for cleaning can be reduced because the quantity of attached substances is small.

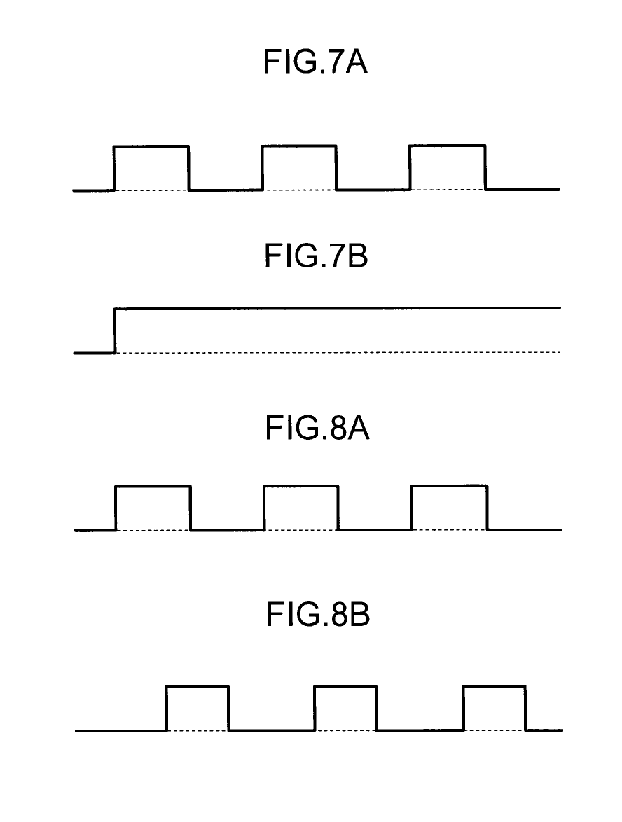

Regarding turn-on and turn-off of the EUV radiation exposing light source 21 of the EUV radiation exposure head 20 and turn-on and turn-off of the ionizer 40, the timing charts show driving states of the EUV radiation exposing light source of the EUV radiation exposure head and the ionizer in the lithography method according to the present embodiment in FIGS. 7A and 7B, respectively. As described above, in the present embodiment, the ionizer 40 is driven in conjunction with turn-on or turn-off of the EUV radiation exposing light source 21.

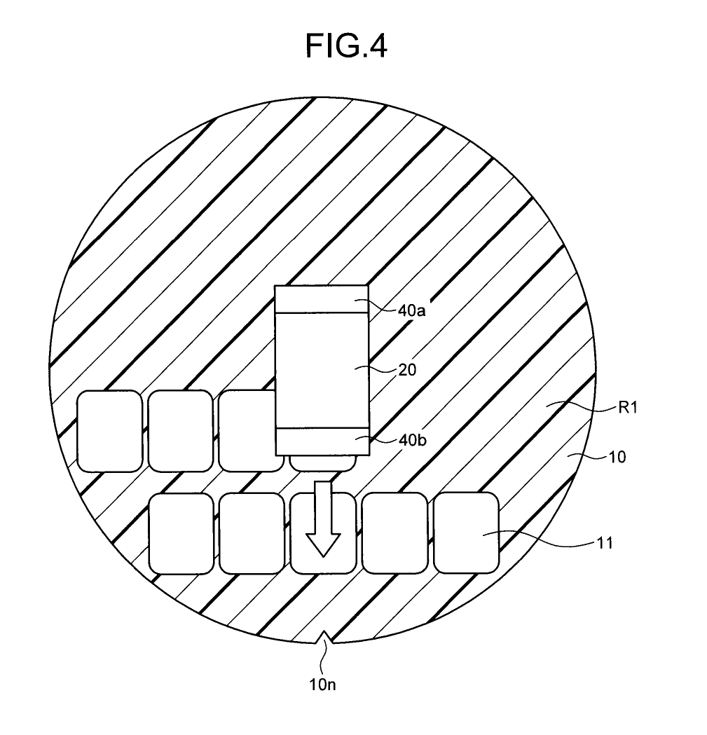

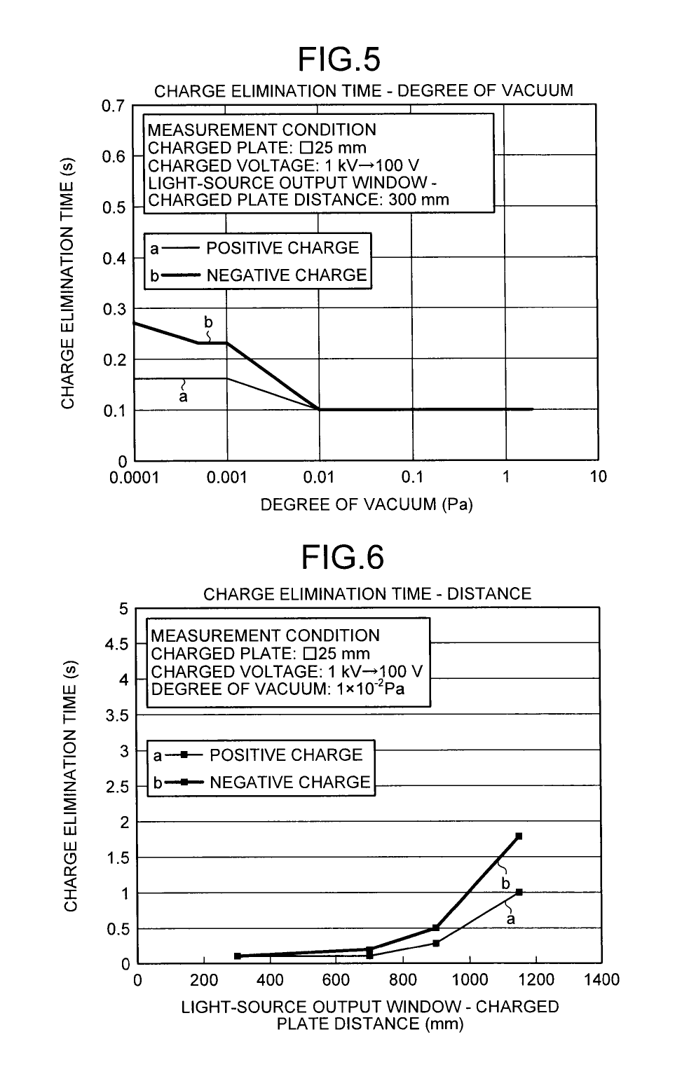

While elimination of charges by the ionizer 40 was performed in this way, the degree of vacuum in the chamber was changed and a relation between the degree of vacuum and the charge elimination time was measured. The obtained result is shown in FIG. 5. In this case, a charged plate of a 25-millimeter square was used and a time to change a charged voltage from 1 kilovolt to 100 volts was measured. At that time, the distance between a light-source output window and the charged plate was 300 millimeters. A curve “a” shows a result measured in a case where positive charges are eliminated and a curve “b” shows a result measured in a case where negative charges are eliminated. It is found that the charge elimination time needs to be longer when the degree of vacuum is higher than 0.01 Pascal while the charge elimination time suffices to be about 0.1 second when the degree of vacuum exceeds 0.01 Pascal.

A relation between the charge elimination time and the distance between a light-source output window and a charged plate in a case where the degree of vacuum in the chamber was fixed to 0.01 Pascal and the distance was increased was also measured. The obtained result is shown in FIG. 6. Also in this case, a charged plate of a 25-millimeter square was used and a time to change a charged voltage from 1 kilovolt to 100 volts was measured. A curve “a” shows a result measured in a case where positive charges are eliminated and a curve “b” shows a result measured in a case where negative charges are eliminated. These measurement results indicate that a longer charge elimination time is required when the distance between the light-source output window and the charged plate exceeds 700 millimeters.

According to the first embodiment, when EUV light radiation is performed to the photoresist R1 applied onto the surface of the wafer 10 using the EUV radiation exposure head 20, soft X-ray radiation using the ionizer 40 is always performed to degas including organic compounds generated after the EUV light radiation. As shown by the timing chart of FIG. 7B, when the EUV radiation exposing light source for EUV light radiation is turned on (FIG. 7A), the ionizer 40 is brought into an always-on state regardless of turn-on or turn-off of the EUV radiation exposing light source. In this way, soft X-ray radiation by the ionizer 40 eliminates charges of charged degas immediately after generation of the degas and thus attachment of the degas to various interfaces in the apparatus can be suppressed. Accordingly, the use amount of hydrogen to be used for cleaning of attached substances can be reduced.

As explained above, soft X-ray radiation is performed by the ionizer 40 to degas including organic compounds that is generated from the photoresist R1 after EUV light radiation in the EUV radiation exposure apparatus, thereby eliminating charges to suppress attachment of generated degas onto the photoresist and to the inside of the apparatus. As a result, an effect that the use amount of hydrogen to be used for cleaning can be reduced by suppressing attachment of the degas to the inside of the apparatus can be obtained. Particularly when the apparatus is used in high vacuum, the apparatus is easily charged and contamination of the optical elements is serious. However, with the configuration according to the present embodiment, elimination of charges can be performed quite easily and contamination is suppressed. Therefore, the configuration is particularly effective for the EUV radiation exposure apparatus according to the present embodiment, which is used in high vacuum.

In the present embodiment, because the ion generation port 40a that is provided on the downstream side of the EUV radiation exposure head 20 among the ion generation ports 40a and 40b of the ionizer 40 is driven, degas generated by exposure can be efficiently subject to charge elimination immediately after generation of the degas. When the wafer stage moves in the opposite direction, the ion generation port 40b provided at the opposite position to the ion generation port 40a is driven to realize efficient charge elimination. When both of the ion generation ports 40a and 40b are driven and charges are eliminated on the upstream and downstream sides of the EUV radiation exposure head, more reliable charge elimination can be performed.

In the EUV radiation exposure apparatus according to the present embodiment, the ion generation ports 40a and 40b of the ionizer 40 are provided on the upstream and downstream sides of the EUV radiation exposure head 20, respectively. Therefore, even when the exposure order, that is, the driving direction of the EUV radiation exposure head 20 is changed, the charge elimination function can be achieved quite easily only by selecting which one of the ion generation ports 40a and 40b is to be driven.

In the EUV radiation exposure apparatus according to the present embodiment, the EUV radiation exposure head 20 is fixed and the mask 23 and the wafer 10 are moved so that the generation position of degas is fixed. Therefore, the vacuum suction device 31 can be installed to achieve the best recovery condition of degas. Alternatively, exposure can be sequentially performed while the EUV radiation exposure head 20 is moved. With this configuration, transport of the wafer can be avoided and thus factors of contamination can be reduced.

### Second Embodiment

While an ionizer is brought into an always-on state in the embodiment described above, ions are radiated in a pulsed manner with a certain time shifted from timings where the EUV radiation exposing light source 21 is turned on as shown by the timing charts showing driving timings of an EUV radiation exposing light source and an ionizer in FIGS. 8A and 8B, respectively in this embodiment. Because other parts of the present embodiment are identical to those of the above embodiment, explanations thereof will be omitted.

According to the present embodiment, because soft X-ray radiation is performed in a pulsed manner, charge elimination is realized more efficiently. A shift time during which the driving timings of the EUV radiation exposing light source and the ionizer are shifted is preferably about one-third to a half of a pulse width after driving of the EUV radiation exposing light source.

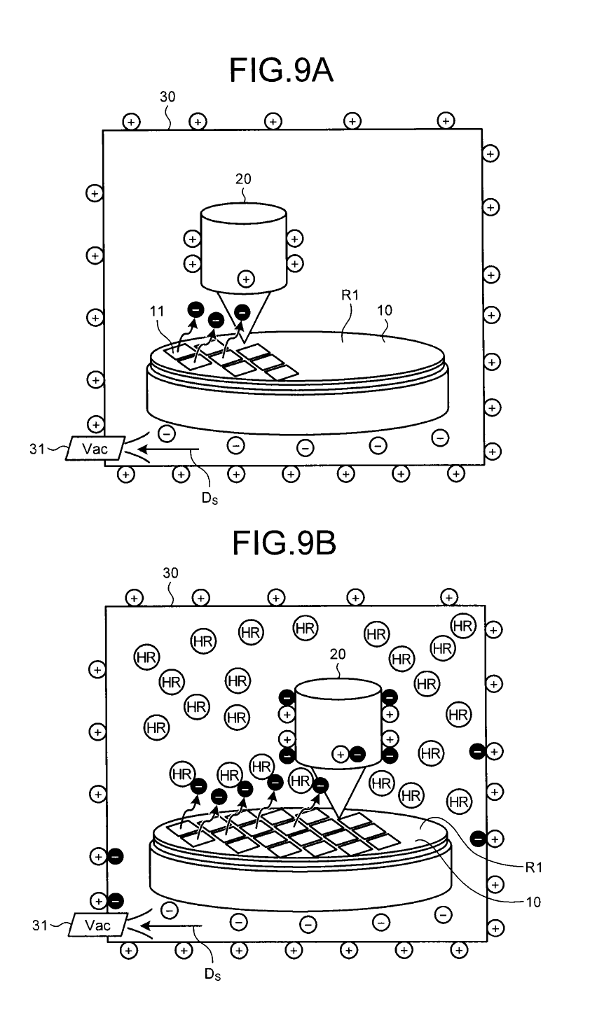

For comparison, cross-sectional views schematically illustrating a configuration of an EUV radiation exposure apparatus not using the ionizer and a configuration of a method of lithography by the EUV radiation exposure apparatus are shown in FIGS. 9A and 9B. As apparent from the comparison with FIGS. 1A and 1B, because the inside of the chamber 30 is in high vacuum, it is easily charged. Accordingly, degas including organic compounds that is generated from a photoresist due to exposure is also charged and is attached to various interfaces in the exposure apparatus to contaminate the inside of the apparatus (FIG. 9A). Furthermore, in the EUV radiation exposure apparatus, a large amount of hydrogen that requires caution in handling is used to clean and recover the degas including the organic compounds generated from the photoresist and there are many hydrogen radicals HR as shown in FIG. 9B.

On the other hand, in the EUV radiation exposure apparatus according to the embodiments of the present invention, when EUV light radiation is performed from the EUV radiation exposure head 20 to the photoresist R1 on the surface of the wafer 10, soft X-ray radiation is performed by the ionizer 40 to degas including organic compounds, which is generated after the EUV light radiation, thereby neutralizing charged degas. With the soft X-ray radiation by the ionizer 40, the degas is neutralized to eliminate charges in the chamber 30 immediately after generation as shown in FIGS. 1A and 1B.

As described above, in the EUV radiation exposure apparatus according to the embodiments of the present invention, radiation of EUV light to the photoresist in the EUV radiation exposure apparatus decomposes or desorbs a resin constituting the photoresist, whereby degas including organic compounds is generated. Because the inside of the EUV radiation exposure apparatus is in vacuum, the degas including the organic compounds is easily charged and is attached to various interfaces in the apparatus due to charging, thereby causing contamination. Accordingly, in the above embodiments, the ionizer 40 using vacuum ultraviolet light is mounted on the EUV radiation exposure head 20 to suppress the contamination. By mounting the ionizer 40 on the EUV radiation exposure head 20 in the EUV radiation exposure apparatus, the degas including organic compounds that is generated from the photoresist R1 and is charged after radiation of EUV light is subject to charge elimination at the same time as generation. By the charge elimination, the degas becomes difficult to attach to the interfaces and contamination in the apparatus can be suppressed. Accordingly, the frequency of cleaning in the apparatus can be reduced and the use amount of hydrogen to be used for cleaning can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An EUV radiation exposure apparatus comprising:
a vacuum chamber;
an EUV radiation exposing light source installed in the vacuum chamber; and
an ionizer that is installed in the vacuum chamber and is driven in conjunction with the driving of the EUV radiation exposing light source to generate positive or negative ions.

2. The EUV radiation exposure apparatus according to claim 1, wherein the ionizer is installed in such a manner that an ion generation port is arranged on an optical path between areas where light from the EUV radiation exposing light source focuses on a processing target object and the EUV radiation exposing light source.

3. The EUV radiation exposure apparatus according to claim 2, wherein
the EUV radiation exposing light source is attached to an EUV radiation exposure head which is relatively movable against the processing target object, and
the ionizer is fixed to the EUV radiation exposure head.

4. The EUV radiation exposure apparatus according to claim 3, wherein the EUV radiation exposure head is movable against the processing target object.

5. The EUV radiation exposure apparatus according to claim 1, wherein the ionizer has two ion generation ports at opposite positions on upstream and downstream sides of the EUV radiation exposing light source, respectively.

6. The EUV radiation exposure apparatus according to claim 5, wherein the ionizer is activated or deactivated in conjunction with activation and deactivation of the EUV radiation exposing light source.

7. The EUV radiation exposure apparatus according to claim 5, wherein the ionizer is activated or deactivated with a delay time according to the activation and deactivation of the EUV radiation exposing light source.

8. The EUV radiation exposure apparatus according to claim 1, wherein the ionizer uses electron beams of a wavelength from 115 nanometers to 400 nanometers.

9. The EUV radiation exposure apparatus according to claim 8, wherein the ionizer uses electron beams of a wavelength from 150 nanometers to 180 nanometers.

10. A method of lithography comprising:
selectively radiating EUV light generated by an EUV radiation exposing light source installed in a vacuum chamber to a processing target object including an EUV resist layer and forming a latent image on the EUV resist layer; and
driving an ionizer, thereby neutralizing a reaction product generated when the EUV light reacts to the EUV resist layer to form a latent image.

11. The method of lithography according to claim 10, wherein the ionizer radiates ions on an optical path between an area where the EUV radiation exposing light source focuses light on the processing target object and the EUV radiation exposing light source.

12. The method of lithography according to claim 10, wherein the ionizer is driven in conjunction with turn-on or turn-off of the EUV radiation exposing light source.

13. The method of lithography according to claim 12, wherein the ionizer is fixed to an EUV radiation exposure head and the ionizer is relatively moved with respect to the processing target object.

14. The method of lithography according to claim 13, wherein the forming a latent image includes sequentially performing exposure while the EUV radiation exposure head is moved with respect to the processing target object.

15. The method of lithography according to claim 10, wherein
the ionizer includes two ion generation ports at opposite positions on upstream and downstream sides of the EUV radiation exposing light source, respectively, and
the forming a latent image includes performing exposure while ions are radiated from one of the two ion generation ports located on a downstream side of the processing target object.

16. The method of lithography according to claim 15, wherein the forming a latent image includes controlling the ionizer to be activated or deactivated according to the activation and deactivation of the EUV radiation exposing light source.

17. The method of lithography according to claim 15, wherein the forming a latent image includes controlling the ionizer to be activated or deactivated with a delay time according to the activation and deactivation of the EUV radiation exposing light source.

18. The method of lithography according to claim 10, wherein the forming a latent image includes neutralizing a reaction product with electron beams of a wavelength from 115 nanometers to 400 nanometers, where the electron beams being obtained from the ionizer.

19. The method of lithography according to claim 10, wherein the forming a latent image includes neutralizing a reaction product with electron beams of a wavelength from 150 nanometers to 180 nanometers, where the electron beams being obtained from the ionizer.
